(19) United States
(12) Patent Application Publication
(10) Pub. No.: US 2016/0381792 A1
(43) Pub. Date: Dec. 29, 2016

(54) PRINTED CIRCUIT BOARD AND METHOD OF MANUFACTURING THE SAME

(71) Applicant: Samsung Electro-Mechanics Co., Ltd., Suwon-si (KR)

(72) Inventors: Jee-Soo MOK, Yongin-si (KR); Young-Gwan KO, Seoul (KR); Jung-Hyun PARK, Suwon-si (KR); Jae-Ean LEE, Busan (KR); Young Kuk KO, Seoul (KR); Going-Sik KIM, Suwon-si (KR)

(73) Assignee: Samsung Electro-Mechanics Co., Ltd., Suwon-si (KR)

(21) Appl. No.: 15/174,563

(22) Filed: Jun. 6, 2016

(30) Foreign Application Priority Data
Jun. 29, 2015 (KR) 10-2015-0092321

(51) Int. Cl. H05K 1/02; H05K 3/46; H05K 3/40; H05K 1/11; H05K 3/00

(52) U.S. Cl. CPC H05K 1/0298; H05K 1/115; H05K 1/0212; H05K 3/0058; H05K 3/4038; H05K 3/4661; H05K 2201/09827

(57) ABSTRACT

A printed circuit board in accordance with an embodiment includes a core layer, a photo imagable dielectric layer, and an inner circuit layer. The core layer includes a core stiffener layer, a first metal layer formed on an upper surface of the core stiffener layer, and a second metal layer formed on a lower surface of the core stiffener layer. The photo imagable dielectric layer is formed on an upper surface and a lower surface of the core layer. The inner circuit layer is formed on the photo imagable dielectric layer.

### CROSS-REFERENCE TO RELATED APPLICATIONS

This application claims the benefit under 35 USC 119(a) of Korean Patent Application No. 10-2015-0092321, filed with the Korean Intellectual Property Office on Jun. 29, 2015, the disclosure of which is incorporated herein by reference in its entirety.

### BACKGROUND

1. Field

The following description relates to a printed circuit board and a method of manufacturing a printed circuit board.

2. Description of Related Art

Owing to rapid technological advancement, electronic devices have recently become increasingly high-functional. At the same time, electronic components have become lighter, thinner, and smaller. Also, printed circuit boards are required to have multiple functions, more density, and slimmer size.

For the conventional main boards used for mobile devices, an inner circuit is formed on a copper clad laminate (CCL) through circuit forming processes. A copper foil and a prepreg, which is a thermosetting insulating material, are laminated on either surface of an inner core of the inner circuit to form a primary build-up layer through the circuit forming processes.

Further, secondary and tertiary build-up layers are formed by repeating the processes of forming the primary build-up layer. A multilayered build-up main board is manufactured by forming a solder resist and undertaking a backend process.

The prepreg has as an interlayer insulating material that is manufactured in a semi-hardened (B-stage) form by impregnating glass fiber in a thermosetting epoxy resin. The prepreg functions as an interlayer adhesive and as an insulating layer by changing to a fully-hardened (C-stage) state through pressuring and heating processes in the laminating process.

The insulating material formed as described above maintains the stiffness of the main board.

Further, because the circuit is formed using a subtractive process for the inner core described above, a high density circuit cannot be realized, thus, inhibiting a number of build-up layers for the printed circuit board.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a printed circuit board, including a core layer may include a core stiffener layer, a first metal layer formed on an upper surface of the core stiffener layer, and a second metal layer formed on a lower surface of the core stiffener layer; a photo imagable dielectric layer formed on an upper surface and a lower surface of the core layer; and an inner circuit layer formed on the photo imagable dielectric layer.

The printed circuit board may further include: a through via formed by penetrating the core layer between an upper surface and a lower surface of the core layer, wherein the photo imagable dielectric layer is formed in the through via.

The printed circuit board may further include: a heat-dissipating via connecting the inner circuit layer with at least one of the first metal layer and the second metal layer.

The printed circuit board may further include: a ground via connecting the inner circuit layer with at least one of the first metal layer and the second metal layer.

A thickness of the core stiffener layer may be greater than a combined thickness of the first metal layer and the second metal layer.

A combined thickness of the first metal layer and the second metal layer may be greater than a thickness of the core stiffener layer.

A thickness of the first metal layer may be different from a thickness of the second metal layer.

The core stiffener layer may have a resin impregnated in an inorganic stiffener.

The core stiffener layer may further include an organic filler or an inorganic filler.

The inner circuit layer may be formed through a semi additive plating method.

In accordance with another embodiment, there is provided a printed circuit board, may include: a core layer may include a core stiffener layer, a first metal layer formed on an upper surface of the core stiffener layer, and a second metal layer formed on a lower surface of the core stiffener layer; a photo imagable dielectric layer formed on an upper surface and a lower surface of the core layer; an inner circuit layer formed on the photo imagable dielectric layer; a first prepreg layer formed above the photo imagable dielectric layer; and a second prepreg layer formed below the photo imagable dielectric layer.

The printed circuit board may further include: a through via formed by penetrating the core layer between an upper surface and a lower surface of the core layer, wherein the photo imagable dielectric layer is formed in the through via.

The printed circuit board may further include: a heat-dissipating via connecting the inner circuit layer with at least one of the first metal layer and the second metal layer.

The printed circuit board may further include: a ground via connecting the inner circuit layer with at least one of the first metal layer and the second metal layer.

A thickness of the core stiffener layer may be greater than a combined thickness of the first metal layer and the second metal layer.

A combined thickness of the first metal layer and the second metal layer may be greater than a thickness of the core stiffener layer.

A thickness of the first metal layer may be different from a thickness of the second metal layer.

The core stiffener layer may have resin impregnated in an inorganic stiffener.

The core stiffener layer may further include an organic filler or an inorganic filler.

The inner circuit layer may be formed through a semi additive plating method.

A solder resist may be further formed on the first prepreg layer and the second prepreg layer.

In accordance with an embodiment, there is provided a method of manufacturing a printed circuit board, including preparing a core layer may include a core stiffener layer, a first metal layer formed on an upper surface of the core stiffener layer, and a second metal layer formed on a lower surface of the core stiffener layer; laminating a photo imagable dielectric layer on an upper surface and a lower surface of the core layer; forming a through via hole at the through hole; and forming an inner circuit layer and a through via.

The method may further include: forming a through hole in the core layer, wherein the photo imagable dielectric layer may include the through hole formed therein.

The inner circuit layer and the through via may be formed by applying a semi additive plating method on the photo imagable dielectric layer.

The method may further include: forming a first prepreg layer on an upper surface of the photo imagable dielectric layer and forming a second prepreg layer on a lower surface of the photo imagable dielectric layer.

In the preparing of the core layer, a thickness of the core stiffener layer may be greater than a combined thickness of the first metal layer and the second metal layer.

In the preparing of the core layer, a combined thickness of the first metal layer and the second metal layer may be greater than a thickness of the core stiffener layer.

In the preparing of the core layer, a thickness of the first metal layer may be different from a thickness of the second metal layer.

Other features and aspects will be apparent from the following detailed description, the drawings, and the claims.

### BRIEF DESCRIPTION OF DRAWINGS

FIG. 1 is a cross-sectional view illustrating a printed circuit board, in accordance with an embodiment.

FIG. 2A is a cross-sectional view illustrating a core layer during a manufacturing process of a printed circuit board, in accordance with an embodiment.

FIG. 2B is a cross-sectional view illustrating a through hole formed during the manufacturing process of the printed circuit board, in accordance with an embodiment.

FIG. 2C is a cross-sectional view illustrating a photo imagable dielectric layer formed during the manufacturing process of the printed circuit board, in accordance with an embodiment.

FIG. 2D is a cross-sectional view illustrating a through via hole and a heat-dissipating via hole or a ground via hole formed during the manufacturing process of the printed circuit board, in accordance with an embodiment.

FIG. 2E is a cross-sectional view illustrating a through via and an inner circuit layer formed during the manufacturing process of the printed circuit board, in accordance with an embodiment.

FIG. 2F is a cross-sectional view illustrating an additional build-up layer formed during the manufacturing process of the printed circuit board, in accordance with an embodiment.

FIG. 2G is a cross-sectional view illustrating an additional build-up layer formed during the manufacturing process of the printed circuit board, in accordance with an embodiment.

FIG. 2H is a cross-sectional view illustrating an upper prepreg layer and a lower prepreg layer formed during the manufacturing process of the printed circuit board, in accordance with an embodiment.

FIG. 2I is a cross-sectional view illustrating a solder resist layer formed during the manufacturing process of the printed circuit board, in accordance with an embodiment.

FIG. 3A is a cross-sectional view illustrating a combined thickness of a first metal layer and a second metal layer compared to a thickness of a core stiffener layer in the core layer of the printed circuit board, in accordance with an embodiment.

FIG. 3B is a cross-sectional view illustrating a thickness of the core stiffener layer compared to a combined thickness of the first metal layer and the second metal layer, in accordance with an embodiment.

FIG. 3C is a cross-sectional view illustrating a thickness of the first metal layer being different from a thickness of the second metal layer, in accordance with an embodiment.

FIG. 4 is a cross-sectional view illustrating a heat-dissipating via or a ground via formed above and below the printed circuit board, in accordance with an embodiment.

FIG. 5 illustrates a method to manufacture a printed circuit board, in accordance with an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated. Throughout the description of the present disclosure, when describing a certain relevant conventional technology is determined to evade the point of the present disclosure, the pertinent detailed description will be omitted. Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

Hereinafter, certain embodiments will be described in detail with reference to the accompanying drawings.

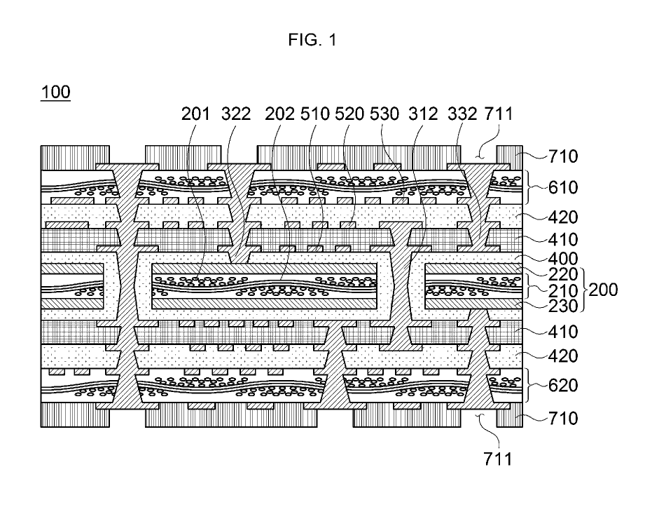

FIG. 1 is a cross-sectional view illustrating a printed circuit board, in accordance with an embodiment.

Referring to FIG. 1, a printed circuit board 100, in accordance with an embodiment, includes a core layer 200 including a core stiffener layer 210, a first metal layer 220 formed on an upper surface of the core stiffener layer 210, and a second metal layer 230 formed on a lower surface of the core stiffener layer 210. A through via 312 is formed in the printed circuit board 100 by penetrating the core layer 200 between an upper surface and a lower surface of the core layer 200. A photo imagable dielectric layer 400 is formed on the upper and lower surfaces of the core layer 200 and in the through via 312. An inner circuit layer 510 is formed on the photo imagable dielectric layer 400.

In this example, the printed circuit board 100 also includes a heat-dissipating via 322 connecting the inner circuit layer 510 with the first metal layer 220 and/or the second metal layer 230 and also includes a ground via 322 connecting the inner circuit layer 510 with the first metal layer 220 and/or the second metal layer 230. A via 332 is also formed on at least one of an upper and a lower portion of the printed circuit board 100 connecting the inner circuit layer 510 with the photo imagable dielectric layer 400.

The via 322 connecting the first metal layer 220 or the second metal layer 230 are utilized as the heat-dissipating via 322 to dissipate a heat or the ground via 322 to ground, depending on the use of the printed circuit board 100.

Conventionally, metal layers of a copper clad laminate (CCL), which corresponds to the core layer 200, have been patterned using a subtractive process to form an inner circuit layer. However, the subtractive process has not been effective or has been minimally effective in realizing a fine circuit.

In the printed circuit board 100, in accordance with an embodiment, the metal layers of the CCL are not used to form the inner circuit layer. Instead, the inner circuit layer 510 is formed using a semi additive plating method on the photo imagable dielectric layer 400 to produce a fine circuit pattern.

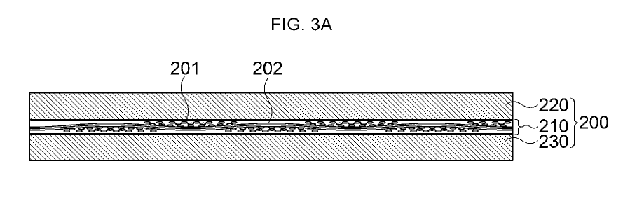

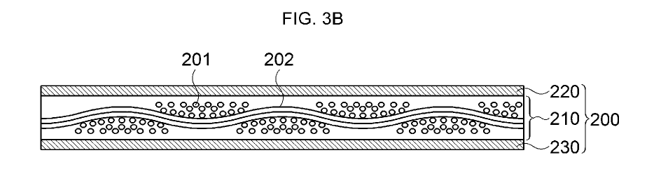

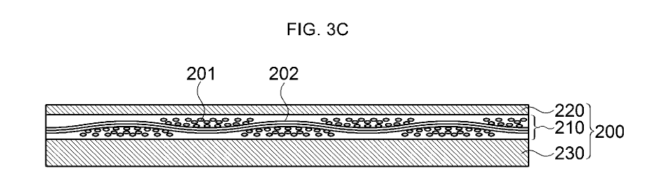

FIG. 3A is a cross-sectional view illustrating a combined thickness of a first metal layer and a second metal layer compared to a thickness of a core stiffener layer in the core layer of the printed circuit board, in accordance with an embodiment. Referring to FIG. 3A, the core layer 200 of the printed circuit board, in accordance with an embodiment, formed in such a way that a combined thickness of the first metal layer 220 and the second metal layer 230 is greater than a thickness of the core stiffener layer 210. Accordingly, the heat-dissipating or grounding performance of the printed circuit board is optimally improved because the first metal layer 220 and the second metal layer 230 are used as a heat transfer path of the heat-dissipating via 322 or as a ground path of the ground via 322, and are relatively thick.

FIG. 3B is a cross-sectional view illustrating a thickness of the core stiffener layer compared to a combined thickness of the first metal layer and the second metal layer, in accordance with an embodiment. Referring to FIG. 3B, the core layer 200 of the printed circuit board, in accordance with another embodiment, is formed in such a way that a thickness of the core stiffener layer 210 is greater than a combined thickness of the first metal layer 220 and the second metal layer 230. In this example, because the core stiffener layer 210 is thick in contrast with the first metal layer 220 and the second metal layer 230, which are thin. The first metal layer 220 and the second metal layer 230 are used as the heat transfer path of the heat-dissipating via 322 or the ground path of the ground via 322. As a result, the printed circuit board of this embodiment inhibits the printed circuit board from warping, thereby improving a reliability.

FIG. 3C is a cross-sectional view illustrating a thickness of the first metal layer being different from a thickness of the second metal layer, in accordance with an embodiment. Referring to FIG. 3C, the core layer 200 of the printed circuit board, in accordance with yet another embodiment, is formed in which thicknesses of the first metal layer 220 and the second metal layer 230 are different from each other. The first metal layer 220 is an upper surface of the printed circuit board and the second metal layer 230 is a lower surface of the printed circuit board. For example, an overall warpage of the printed circuit board is resolved or is improved by forming a metal layer on an upper surface or a lower surface of the printed circuit board having a relatively low wiring density to be thick. For instance, when the wiring density is relatively higher on the upper surface of the printed circuit board than that of the lower surface, the overall wiring densities of the upper surface and the lower surface of the printed circuit board are adjusted by forming the second metal layer 230 to be thicker than the first metal layer 220. As a result, the warpage of the printed circuit board is resolved or improved.

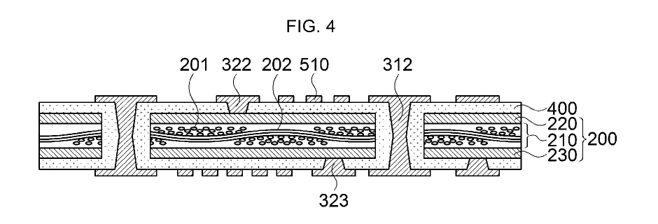

FIG. 4 is a cross-sectional view illustrating a heat-dissipating via or a ground via formed above and below the printed circuit board, in accordance with an embodiment. Referring to FIG. 4, the printed circuit board, in accordance with an embodiment, includes the heat-dissipating via 323 or the ground via 323 formed on a lower surface thereof and on the upper surface thereof. Accordingly, the via 323 formed on the lower surface is used to dissipate the heat generated from the lower surface or as a ground path of a circuit on the lower surface of the printed circuit board.

The printed circuit board, in accordance with an embodiment, has an additional build-up layer laminated thereon. As a result, a multilayered printed circuit board is manufactured by forming additional photo imagable dielectric layers 410, 420 and inner circuit layers 520, 530.

A prepreg may be used for an outermost additional build-up layer. Also, the rigidity of the printed circuit board may be enhanced by laminating a first prepreg layer 610 and a second prepreg layer 620 containing a stiffener and a filler.

A solder resist layer 710 having an opening 711 formed therein is formed on outer layers of the first prepreg layer 610 and the second prepreg layer 620. The solder resist layer 710, in one example, is used as a protective layer of the printed circuit board.

Hereinafter, a method of manufacturing a printed circuit board, in accordance with an embodiment, will be described in detail.

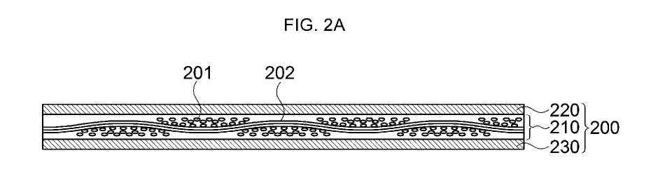

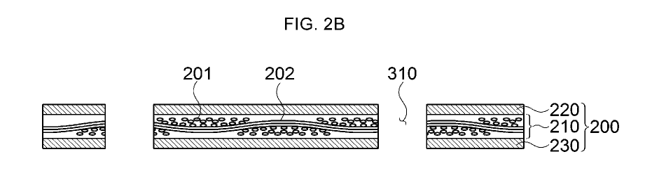

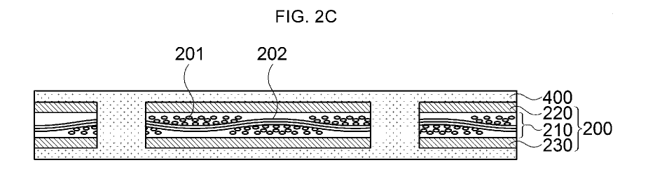

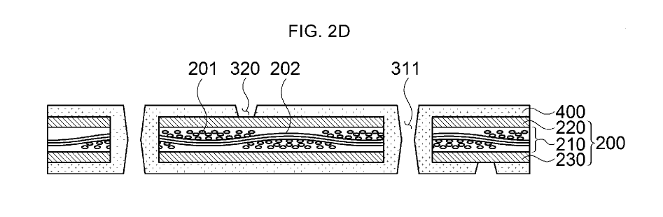

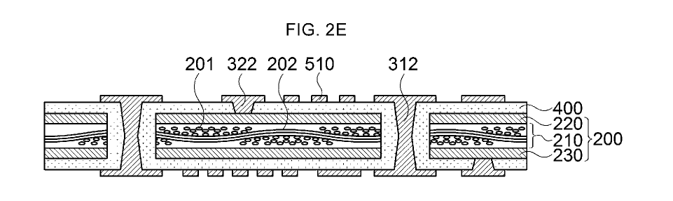

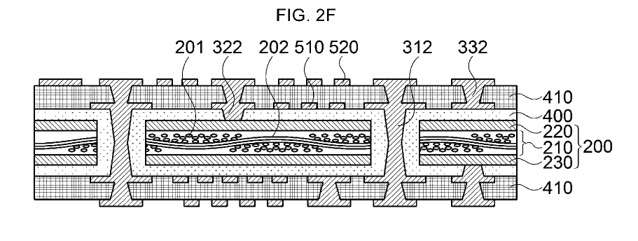

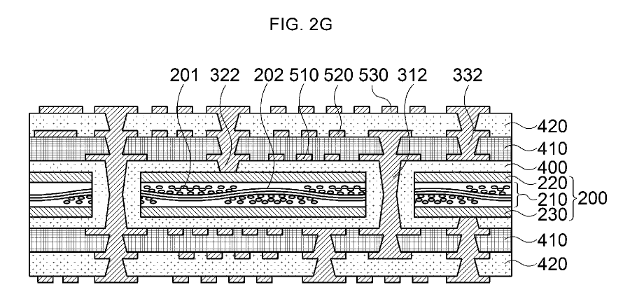

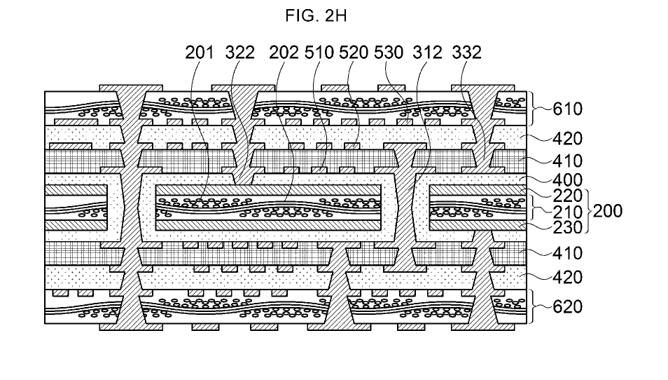

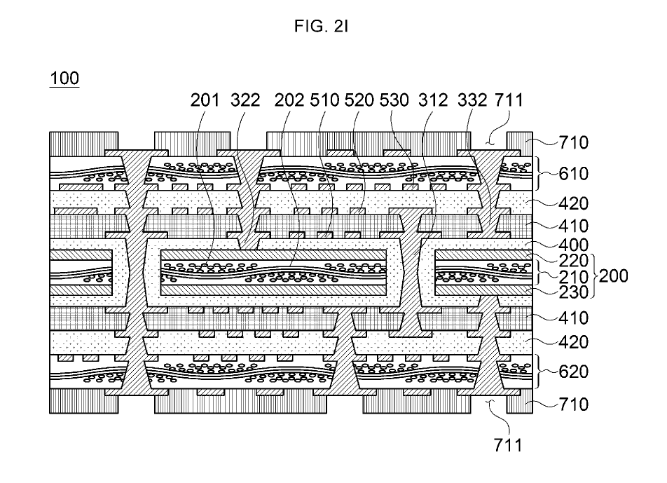

FIG. 2A is a cross-sectional view illustrating a core layer during a manufacturing process of a printed circuit board, in accordance with an embodiment. FIG. 2B is a cross-sectional view illustrating a through hole formed during the manufacturing process of the printed circuit board, in accordance with an embodiment. FIG. 2C is a cross-sectional view illustrating a photo imagable dielectric layer formed during the manufacturing process of the printed circuit board, in accordance with an embodiment. FIG. 2D is a cross-sectional view illustrating a through via hole and a heat-dissipating via hole or a ground via hole formed during the manufacturing process of the printed circuit board, in accordance with an embodiment.

FIG. 2E is a cross-sectional view illustrating a through via and an inner circuit layer formed during the manufacturing process of the printed circuit board, in accordance with an embodiment. FIG. 2F is a cross-sectional view illustrating an additional build-up layer formed during the manufacturing process of the printed circuit board, in accordance with an embodiment. FIG. 2G is a cross-sectional view illustrating an additional build-up layer formed during the manufacturing process of the printed circuit board, in accordance with an embodiment. FIG. 2H is a cross-sectional view illustrating an upper prepreg layer and a lower prepreg layer formed during the manufacturing process of the printed circuit board, in accordance with an embodiment. FIG. 2I is a cross-sectional view illustrating a solder resist layer formed during the manufacturing process of the printed circuit board, in accordance with an embodiment.

Referring to FIG. 2A through FIG. 2I, a method of manufacturing the printed circuit board 100, in accordance with an embodiment, include preparing a core layer 200 including a core stiffener layer 210. The method forms a first metal layer 220 on an upper surface of the core stiffener layer 210, and forms a second metal layer 230 on a lower surface of the core stiffener layer 210. The method forms a through hole 310 in the core layer 200 and a photo imagable dielectric layer 400 is laminated on an upper surface and a lower surface of the core layer 200 having the through hole 310 formed therein. The method forms a through via hole 311 at the through hole 310 through exposure and development. The method also forms an inner circuit layer 510 and a through via 312 on the photo imagable dielectric layer 400 using a semi additive plating method.

In the operations of preparing the core layer 200, the core stiffener layer 210 includes a glass fiber 202 and a filler 201 such as, for example, an organic filler or an inorganic filler.

Thicknesses of the first metal layer 220 and the second metal layer 230 are adjusted by, for example, grinding. Through this adjustment, it is possible to prepare various kinds of core layer, for example, the core layer 200 (shown in FIG. 3B), in which a thickness of the core stiffener layer 210 is greater than a combined thickness of the first metal layer 220 and the second metal layer 230. Another core layer 200 may be one, as shown in FIG. 3A, in which the combined thickness of the first metal layer 220 and the second metal layer 230 is greater than the thickness of the core stiffener layer 210. Another core layer 200, as shown in FIG. 3C, includes the first metal layer 220 and the second metal layer 230 with different thicknesses from each other.

In the operation of forming the through hole 310 in the core layer 200, the through hole 310 is machined using a drilling process.

In the operation of laminating the photo imagable dielectric layer 400, a photosensitive epoxy is used for the photo imagable dielectric layer 400, but the material for the photo imagable dielectric layer 400 may not be limited thereto.

The photo imagable dielectric layer 400 is formed by laminating a photo imagable dielectric. The photo imagable dielectric layer 400 is formed on the upper and lower surfaces of the core layer 200. In an alternative embodiment, the photo imagable dielectric layer 400 on the upper and lower surfaces of the core layer 200 and within the through hole 310, while being compressed with heat and pressure.

In the operation of forming the through via hole 311, the through via hole 311 is formed by protecting a portion, at which the through via hole 311 is to be formed, using a mask lest the photo imagable dielectric layer 400 should be hardened by, for example, a laser. An exposure and development processes uses a laser.

Moreover, it is possible to simultaneously form a heat-dissipating via hole 320 or a ground via hole 320 to form the heat-dissipating via 322 or the ground via 322, respectively, by connecting the first metal layer 220 and/or the second metal layer 230 with the inner circuit layer 510.

In the operation of forming the inner circuit layer 510 and the through via 312 on the photo imagable dielectric slayer 400 using a semi additive plating method, a fine circuit pattern is formed on the photo imagable dielectric layer 400 using the semi additive plating method and is used as the inner circuit layer 510.

In the conventional method to form an inner circuit layer by applying the semi additive plating method to a metal layer of a CCL, an etchant is used during a process of etching a circuit. As a result, a circuit pattern has an improper and unworkable aspect ratio in a cross section thereof, making it difficult to form a fine circuit pattern. In contrast, in the method of manufacturing a printed circuit board, in accordance with an embodiment, instead of using the metal layer of the CCL as the inner circuit layer, the inner circuit layer 510 is formed by laminating a photo imagable dielectric layer and using the semi additive plating method on the photo imagable dielectric layer. As a result, a fine circuit pattern is formed with a proper and workable aspect ratio in the cross section of the circuit pattern.

The through via hole 311 has an inside thereof filled with a plating layer, which is formed during the plating by the semi additive plating method. The plating layer allows the through via 312 to be formed. Plating may be applied to the heat-dissipating via hole 320 or the ground via hole 320 to allow the heat-dissipating via 322 or the ground via 322 to be formed.

Additional photo imagable dielectric layers 410, 420 may be formed by repeating the step of laminating the photo imagable dielectric layer 410 and the step of using the semi additive plating method, and additional inner circuit layers 520, 530 and an interlayer via 322 for a signal and electrical transfer between the inner circuit layers may be formed.

After the additional photo imagable dielectric layers 410, 420 and the additional inner circuit layers 520, 530 are formed, a first prepreg layer 610 and a second prepreg layer 620 are formed. In this example, the first prepreg layer 610 and the second prepreg layer 620 include a stiffener and a filler, contributing to maintaining a rigidity in the printed circuit board.

Afterwards, a solder resist layer 710 is formed for use as a protective layer. In this example, the solder resist layer 710 includes an opening 711 for electrical connection with an external electronic component.

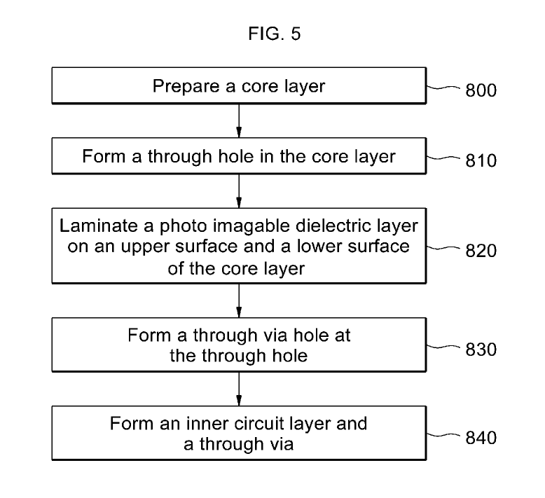

FIG. 5 illustrates a method to manufacture a printed circuit board, in accordance with an embodiment. The operations illustrated in the method of FIG. 5 were previously discussed with respect to FIGS. 2A through 2I. A description of these functions are hereby incorporated. The method of manufacturing a printed circuit board, as illustrated in FIG. 5, includes, at operation 800, preparing a core layer including a core stiffener layer, a first metal layer formed on an upper surface of the core stiffener layer, and a second metal layer formed on a lower surface of the core stiffener layer. At operation 810, the method forms a through hole in the core layer. At operation 820, the method laminates a photo imagable dielectric layer on an upper surface and a lower surface of the core layer having the through hole formed therein. At operation 830, the method forms a through via hole at the through hole by use of exposure and development. At operation 840, the method forms an inner circuit layer and a through via by applying a semi additive plating method on the photo imagable dielectric layer.

While this disclosure includes specific examples, it will be apparent to one of ordinary skill in the art that various changes in form and details may be made in these examples without departing from the spirit and scope of the claims and their equivalents.

The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board, comprising:
a core layer comprising a core stiffener layer, a first metal layer formed on an upper surface of the core stiffener layer, and a second metal layer formed on a lower surface of the core stiffener layer;
a photo imagable dielectric layer formed on an upper surface and a lower surface of the core layer; and
an inner circuit layer formed on the photo imagable dielectric layer.

2. The printed circuit board as set forth in claim 1, further comprising:
a through via formed by penetrating the core layer between an upper surface and a lower surface of the core layer, wherein the photo imagable dielectric layer is formed in the through via.

3. The printed circuit board as set forth in claim 1, further comprising:
a heat-dissipating via connecting the inner circuit layer with at least one of the first metal layer and the second metal layer.

4. The printed circuit board as set forth in claim 1, further comprising:
a ground via connecting the inner circuit layer with at least one of the first metal layer and the second metal layer.

5. The printed circuit board as set forth in claim 1, wherein a thickness of the core stiffener layer is greater than a combined thickness of the first metal layer and the second metal layer.

6. The printed circuit board as set forth in claim 1, wherein a combined thickness of the first metal layer and the second metal layer is greater than a thickness of the core stiffener layer.

7. The printed circuit board as set forth in claim 1, wherein a thickness of the first metal layer is different from a thickness of the second metal layer.

8. The printed circuit board as set forth in claim 1, wherein the core stiffener layer has a resin impregnated in an inorganic stiffener.

9. The printed circuit board as set forth in claim 1, wherein the core stiffener layer further comprises an organic filler or an inorganic filler.

10. The printed circuit board as set forth in claim 1, wherein the inner circuit layer is formed through a semi additive plating method.

11. A printed circuit board, comprising:
a core layer comprising a core stiffener layer, a first metal layer formed on an upper surface of the core stiffener layer, and a second metal layer formed on a lower surface of the core stiffener layer;
a photo imagable dielectric layer formed on an upper surface and a lower surface of the core layer;
an inner circuit layer formed on the photo imagable dielectric layer;
a first prepreg layer formed above the photo imagable dielectric layer; and
a second prepreg layer formed below the photo imagable dielectric layer.

12. The printed circuit board as set forth in claim 11, further comprising:
a through via formed by penetrating the core layer between an upper surface and a lower surface of the core layer, wherein the photo imagable dielectric layer is formed in the through via.

13. The printed circuit board as set forth in claim 11, further comprising:
a heat-dissipating via connecting the inner circuit layer with at least one of the first metal layer and the second metal layer.

14. The printed circuit board as set forth in claim 11, further comprising:
a ground via connecting the inner circuit layer with at least one of the first metal layer and the second metal layer.

15. The printed circuit board as set forth in claim 11, wherein a thickness of the core stiffener layer is greater than a combined thickness of the first metal layer and the second metal layer.

16. The printed circuit board as set forth in claim 11, wherein a combined thickness of the first metal layer and the second metal layer is greater than a thickness of the core stiffener layer.

17. The printed circuit board as set forth in claim 11, wherein a thickness of the first metal layer is different from a thickness of the second metal layer.

18. The printed circuit board as set forth in claim 11, wherein the core stiffener layer has resin impregnated in an inorganic stiffener.

19. The printed circuit board as set forth in claim 11, wherein the core stiffener layer further comprises an organic filler or an inorganic filler.

20. The printed circuit board as set forth in claim 11, wherein the inner circuit layer is formed through a semi additive plating method.

21. The printed circuit board as set forth in claim 11, wherein a solder resist is further formed on the first prepreg layer and the second prepreg layer.

22. A method of manufacturing a printed circuit board, comprising:
preparing a core layer comprising a core stiffener layer, a first metal layer formed on an upper surface of the core stiffener layer, and a second metal layer formed on a lower surface of the core stiffener layer;
laminating a photo imagable dielectric layer on an upper surface and a lower surface of the core layer;
forming a through via hole at the through hole; and
forming an inner circuit layer and a through via.

23. The method as set forth in claim 22, further comprising:
forming a through hole in the core layer, wherein the photo imagable dielectric layer comprises the through hole formed therein.

24. The method as set forth in claim 22, wherein the inner circuit layer and the through via are formed by applying a semi additive plating method on the photo imagable dielectric layer.

25. The method as set forth in claim 22, further comprising:
forming a first prepreg layer on an upper surface of the photo imagable dielectric layer and forming a second prepreg layer on a lower surface of the photo imagable dielectric layer.

26. The method as set forth in claim 22, wherein, in the preparing of the core layer, a thickness of the core stiffener layer is greater than a combined thickness of the first metal layer and the second metal layer.

27. The method as set forth in claim 22, wherein, in the preparing of the core layer, a combined thickness of the first metal layer and the second metal layer is greater than a thickness of the core stiffener layer.

28. The method as set forth in claim 22, wherein, in the preparing of the core layer, a thickness of the first metal layer is different from a thickness of the second metal layer.
